(19) United States
(12) Patent Application Publication
(10) Pub. No.: US 2013/0048359 A1
(43) Pub. Date: Feb. 28, 2013

(54) SUBSTRATE WITH SPRING TERMINAL AND METHOD OF MANUFACTURING THE SAME

(71) Applicant: Yoshihiro IHARA, Nagano (JP)

(72) Inventor: Yoshihiro IHARA, Nagano (JP)

(73) Assignee: Shinko Electric Industries Co., Ltd., Nagano-shi (JP)

(21) Appl. No.: 13/584,962

(22) Filed: Aug. 14, 2012

(30) Foreign Application Priority Data
Aug. 29, 2011 (JP) 2011-185560

(51) Int. Cl. H05K 1/02; H05K 3/34

(52) U.S. Cl. 174/258; 29/840

(57) ABSTRACT

A substrate with spring terminals includes a substrate including a connection pad, a spring terminal whose connection portion is connected to the connection pad by a solder layer, and a resin portion formed to cover a side surface of the solder layer, thereby the failure that the spring terminal falls down is prevented.

### CROSS-REFERENCE TO RELATED APPLICATIONS

This application is based upon and claims the benefit of priority of the prior Japanese Patent Application No. 2011-185560, filed on Aug. 29, 2011, the entire contents of which are incorporated herein by reference.

### FIELD

It is related to a substrate with spring terminals, which is applicable to a mounting socket used for the mounting of a semiconductor package, or the like, and a method of manufacturing the same.

### BACKGROUND

In the prior art, in view of facility in the exchange work of the semiconductor package, there is a case that the semiconductor package is mounted on the motherboard via the mounting sockets. Also, when an inspection of the semiconductor device is performed, the semiconductor device is connected to the wiring substrate via the inspecting sockets.

Both such mounting socket and such inspecting socket include a spring terminal having the spring property as the external connection terminal to which the semiconductor package is connected.

A related art is disclosed in Japanese Laid-open Patent Publication No. 2010-277829.

In the prior art, when the mounting socket is mounted on the mounting substrate by the reflow soldering, there is the fear that the solder used to fix the spring terminal melts again and the spring terminal falls down.

### SUMMARY

According to one aspect disclosed hereinafter, there is provided a substrate with spring terminals, which includes a substrate including a connection pad, a spring terminal whose connection portion is connected to the connection pad by a solder layer, and a reinforcing resin portion formed to cover a side surface of the solder layer.

Also, according to another aspect disclosed hereinafter, there is provided a method of manufacturing a substrate with spring terminals, which includes providing a resin contained solder material on a connection pad of a substrate including the connection pad, and arranging a connection portion of a spring terminal on the resin contained solder material, and then connecting the connection portion of the spring terminal to the connection pad by a solder layer and forming a reinforcing resin portion covering a side surface of the solder layer, by performing a reflow heating.

Also, according to still another aspect disclosed hereinafter, there is provided a method of manufacturing a substrate with spring terminals, which includes providing a solder material on a connection pad of a substrate including the connection pad, arranging a connection portion of a spring terminal on the solder material, and then connecting the connection portion of the spring terminal to the connection pad by a solder layer, by performing a reflow heating, and forming a reinforcing resin portion covering a side surface of the solder layer.

The object and advantages of the invention will be realized and attained by means of the elements and combination particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a sectional view (#1) for explaining a preliminary matter;

FIG. 2 is a sectional view (#2) for explaining the preliminary matter;

FIGS. 3A and 3B are sectional views (#1) depicting a method of manufacturing a substrate with spring terminals according to a first embodiment;

FIGS. 4A and 4B are sectional views (#2) depicting the method of manufacturing the substrate with spring terminals according to the first embodiment;

FIGS. 5A and 5B are sectional view and plan view (#3) depicting the method of manufacturing the substrate with spring terminals according to the first embodiment;

FIG. 6 is a sectional view depicting a substrate with spring terminals according to the first embodiment;

FIG. 7 is a sectional view depicting a state that the substrate with spring terminals in FIG. 6 is connected to a mounting substrate;

FIG. 8 is a sectional view depicting a state that a semiconductor package is mounted on the substrate with spring terminals connected to the mounting substrate in FIG. 7;

FIGS. 9A and 9B are sectional views (#1) depicting a method of manufacturing a substrate with spring terminals according to a second embodiment;

FIGS. 10A and 10B are sectional view and plan view (#2) depicting the method of manufacturing the substrate with spring terminals according to the second embodiment;

FIG. 11 is a sectional view depicting a substrate with spring terminals according to the second embodiment;

FIG. 12 is a sectional view depicting a substrate with spring terminals according to a first variation of the second embodiment;

FIG. 13 is a sectional view depicting a substrate with spring terminals according to a second variation of the second embodiment; and

FIG. 14 is a sectional view depicting a substrate with spring terminals according to a third variation of the second embodiment.

### DESCRIPTION OF EMBODIMENTS

Embodiments will be explained with reference to the accompanying drawings hereinafter.

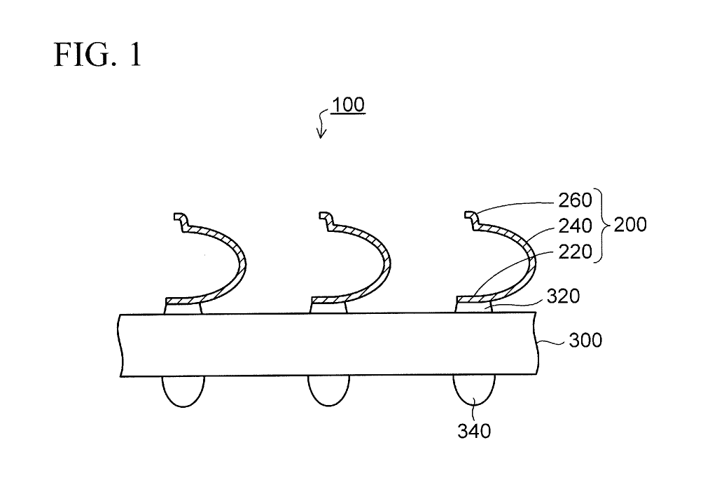

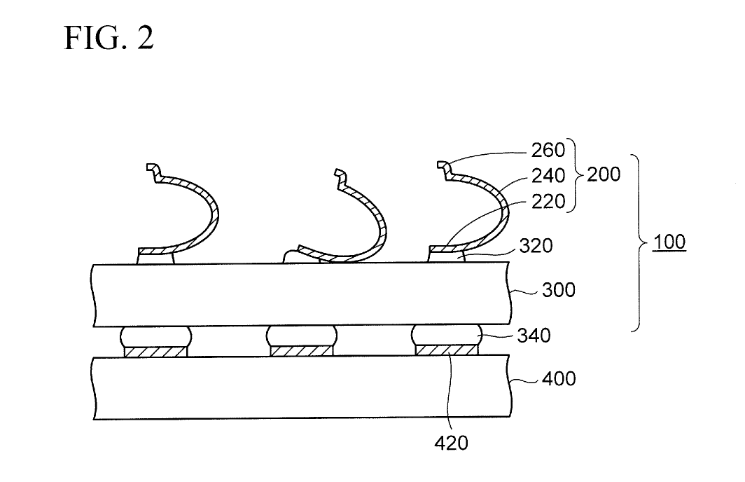

Prior to the explanation of embodiments, the preliminary matter to be set forth as a basis will be explained hereunder. FIG. 1 and FIG. 2 are sectional views explaining a preliminary matter.

As depicted in FIG. 1, in a substrate with spring terminals 100 explained in the preliminary matter, a connection portion 220 of a spring terminal 200, which includes the connection portion 220, a spring portion 240, and a contact portion 260, is fixed to connection pads (not shown) of a wiring substrate 300 by a solder layer 320 respectively. Solder bumps 340 are provided on the lower surface side of the wiring substrate 300 as the external connection terminals.

Then, as depicted in FIG. 2, the solder bumps 340 of the substrate with spring terminals 100 are arranged on connection electrodes 420 of a mounting substrate 400 (motherboard), and then the reflow heating is performed. By this matter, the solder bumps 340 of the substrate with spring terminals 100 are joined to the connection electrodes 420 of the mounting substrate 400.

At this time, when the reflow heating is performed, the solder layer 320 fixing the spring terminal 200 melts again, thereby in some case the spring terminal 200 moves and falls down (the spring terminal 200 depicted in the center of FIG. 2).

In the case that this substrate with spring terminals 100 is used as the socket, the connection electrode of the semiconductor package is connected to the contact portion 260 of the spring terminal 200. As a result, when the spring terminal 200 falls down, the connection failure of the semiconductor package is caused.

The disadvantages mentioned above can be solved by using the substrates with spring terminals according to embodiments explained hereunder.

### First Embodiment

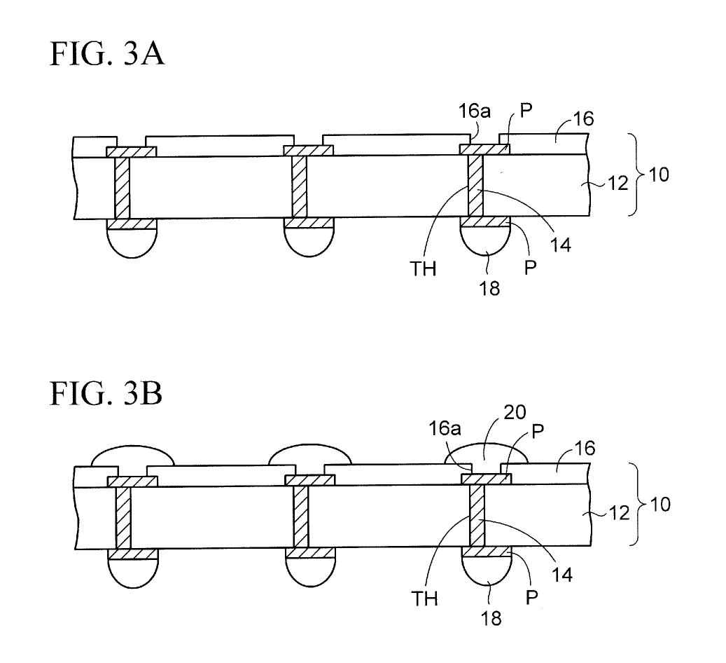

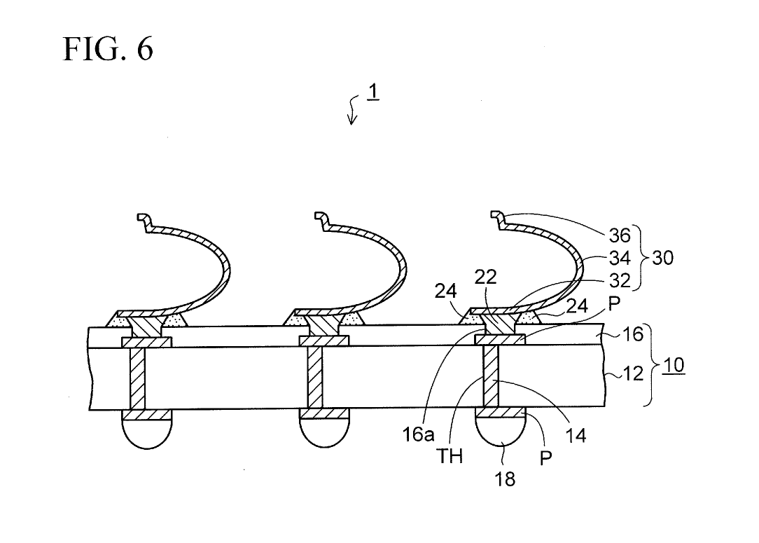

FIG. 3A to FIG. 5B are sectional views depicting a method of manufacturing a substrate with spring terminals according to a first embodiment, and FIG. 6 is a sectional view depicting a substrate with spring terminals according to the first embodiment.

In the method of manufacturing the substrate with spring terminals according to the first embodiment, as depicted in FIG. 3A, a wiring substrate 10 is prepared. In the wiring substrate 10, through holes TH which penetrate to a thickness direction are formed in an insulating substrate 12, and a penetration electrode 14 is filled in the through holes TH respectively. Connection pads P connected mutually via the penetration electrode 14 are formed on both surface sides of the insulating substrate 12 respectively.

Then, a solder resist 16, in which an opening portion 16a is provided on connection parts of the connection pads P respectively, is formed on the upper surface side of the insulating substrate 12. Also, a solder bump 18 is formed as an external connection terminal on the connection pads P on the lower surface side of the insulating substrate 12 respectively. Also, the solder resist may be formed on the lower surface side of the insulating substrate 12 such that the connection pads P are exposed.

Although not particularly depicted, a predetermined multilayer wiring layer may be formed in the wiring substrate 10. Also, the connection pad P may be arranged like an island, or may arranged at an end part of the leader wiring.

Also, in place of the penetration electrode 14, a through hole plating layer may be formed on a sidewall of the through hole TH, and then the remained hole in the through hole TH may be filled with a resin.

Then, as depicted in FIG. 3B, a resin contained solder paste 20 (resin contained solder material) is coated on the connection pads P on the upper surface side of the wiring substrate 10 respectively. The resin contained solder paste 20 is formed by the screen printing, the dispense method, or the like, and is formed to be separated mutually on each connection pad P like an island.

The resin contained solder paste 20 includes solder particles, resin material and its curing agent, and flux. Then, the resin contained solder paste 20 has such a feature that, when the reflow heating is performed, the solder particles melt and are metallic-bonded to provide the electrical connection, and also the resin that spreads around from the solder toward the outer side is cured to reinforce a mechanical joining strength.

As the resin given in the solder paste, for example, a thermosetting epoxy resin whose curing temperature is 150° C. to 250° C., or the like is used.

Also, as the solder of the resin contained solder paste 20, for example, a tin (Sn)-silver (Ag)-copper (Cu) based lead-free solder is used. Alternatively, a bismuth (Bi)-indium (In) based solder, a tin (Sn)-silver (Ag) based solder, or the like may be used.

An oxide film formed on a surface of the metal layer which is soldered can be removed by the flux included in the resin contained solder paste 20, thereby wettability of the solder can be improved. Also, the flux included in the resin contained solder paste 20 has reactivity to the resin. Therefore, the resin contained solder paste 20 has such a characteristic that the flux does not remain in the solder after the reflow heating is performed.

Here, as the resin contained solder material, the resin contained solder paste 20 is illustrated by example. But the resin contained solder ball having the similar characteristic, or the like may be used.

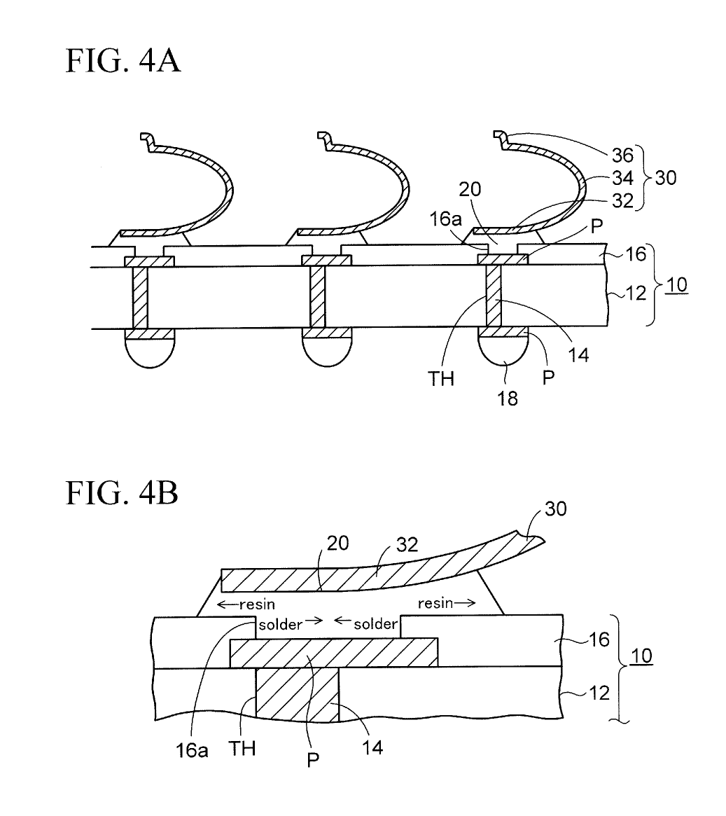

Subsequently, as depicted in FIG. 4A, spring terminals 30 are prepared. The spring terminal 30 includes a connection portion 32 arranged on its lower end side, a spring portion 34 connected to the connection portion 32 and bent like a bow, and a contact portion 36 connected to the spring portion 34 and arranged on its upper end side.

In manufacturing the spring terminal 30, first, a belt-like metal member is obtained by punching or etching a metal plate which is formed of a copper alloy such as a phosphor bronze, a beryllium copper, or the like.

Then, the bend processing is applied to this belt-like metal member, thus this belt-like metal member is bended like a bow. By this matter, the spring terminal 30 including the connection portion 32, the spring portion 34, and the contact portion 36 is obtained. Then, a gold plating layer (not shown) is formed on the connection portion 32 and the contact portion 36 of the spring terminals 30.

The connection portion 32 of the spring terminal 30 is formed like a flat plate whose planar shape has a rectangular shape or a circular shape, for example. As described later, lower surfaces of the connection portions 32 of the spring terminals 30 are opposed to surfaces of the connection pads P of the wiring substrate 10, and are connected to the wiring substrate 10.

Then, the connection portions 32 of the spring terminals 30 are arranged on the resin contained solder pastes 20 which are coated onto the connection pads P of the wiring substrate 10. Then, the reflow heating is performed at a temperature of about 240° C.

Actually, the spring terminal 30 is placed into a large number of terminal container portions of a terminal alignment jig respectively. Then, the reflow heating is performed in such a condition that the connection portion 32 of the spring terminal 30, which is exposed from the terminal container portion, is arranged on the resin contained solder pastes 20 on the wiring substrate 10. After this, the terminal alignment jig is removed from the spring terminals 30.

At this time, as depicted in FIG. 4B, when the reflow heating is performed to the resin contained solder paste 20, the solder particles in the paste melt and gather in the center part and then solidify, and at the same time the resin constituents in the paste move toward a surface of the melted solder together with the flux constituents and then are cured.

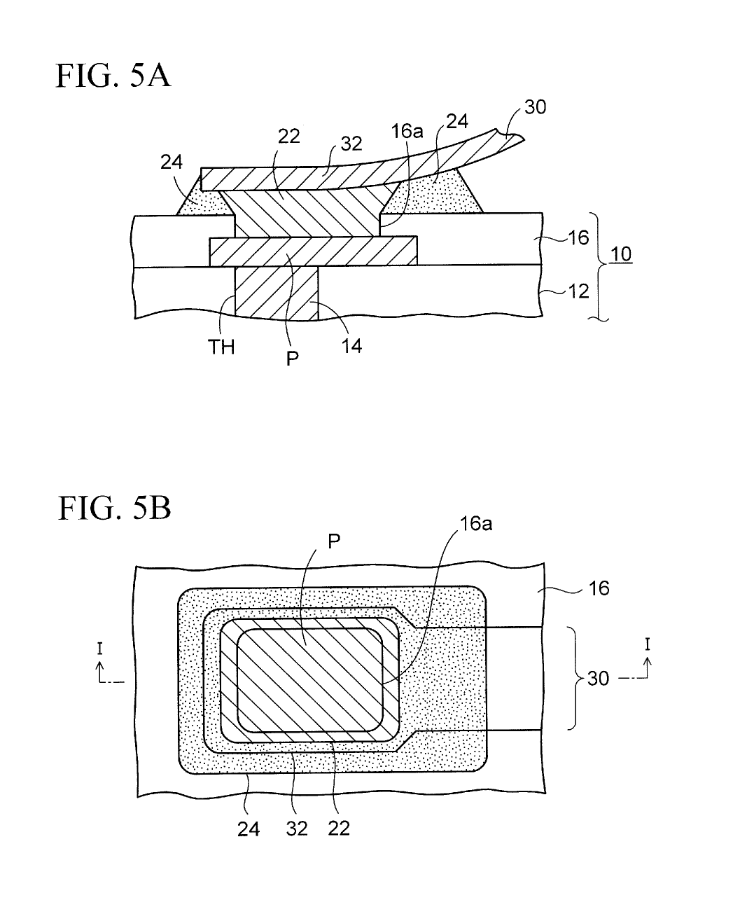

Accordingly, as depicted in FIGS. 5A and 5B, a center main part of the connection portion 32 of the spring terminal 30 is connected to the connection pad P of the wiring substrate 10 by a solder layer 22.

At the same time, a reinforcing resin portion 24 is formed to the outer region from the space between the peripheral part of the connection portion 32 of the spring terminal 30 and the wiring substrate 10 (the solder resist 16). This reinforcing resin portion 24 is formed to cover the side surface of the solder layer 22. FIG. 5A corresponds to a section taken along I-I in a plan view of FIG. 5B.

In this way, the spring terminal 30 is connected to the connection pad P of the wiring substrate 10 by the solder layer 22, and also the mechanical connection strength of the spring terminal 30 is reinforced with the reinforcing resin portion 24.

Here, unlike the present embodiment, the case that the solder paste which does not contain the resin is used will be mentioned hereunder. The flux is also contained in the solder paste. And because the flux remains on the outside of the soldered part after the reflow heating is performed, the cleaning of the flux is needed. This is because the halogen based material is contained in the flux and therefore corrosion is caused easily in the metal layer in such a state that the flux still remains.

In the flux cleaning process, there are 1) the solvent cleaning step, 2) the drying step, 3) the finish cleaning step, and 4) the finish drying step. Therefore, not only the cleaning/drying equipment, the cleaning solvent and its recovery, etc. are needed, thus an increase in cost is caused, but also a considerable processing time is needed, therefore it leads a decrease in the production efficiency.

However, the flux included in the resin contained solder paste 20 employed in the present embodiment has the reactivity to the resin. Therefore, the flux constituent reacts with the resin constituent and then the resin is cured. As a result, no flux remains after the reflow heating is performed, and there is no need to perform the flux cleaning.

In this manner, as depicted in FIGS. 5A and 5B, by using the resin contained solder paste 20, the spring terminal 30 can be connected to the connection pad P of the wiring substrate 10 by the solder layer 22 and, at the same time, the mechanical connection strength of the spring terminal 30 can be reinforced with the reinforcing resin portion 24. Further, because the flux cleaning is not needed, it can contribute to a reduction in cost.

With the above, as depicted in FIG. 6, a substrate with spring terminals 1 of the first embodiment is obtained.

As depicted in FIG. 6, in the substrate with spring terminals 1 of the first embodiment, the center main part of the connection portion 32 of the spring terminal 30 is connected to the connection pad P on the upper surface side of the wiring substrate 10 (FIG. 3A) mentioned above by the solder layer 22.

Also, the reinforcing resin portion 24 is formed to the outer region from the space between the peripheral part of the connection portion 32 of the spring terminal 30 and the wiring substrate 10 (the solder resist 16) (FIG. 5B). This reinforcing resin portion 24 is formed to cover the side surface of the solder layer 22.

In the preferred example mentioned above, the solder layer 22 is formed in the center main part of the connection portion 32 of the spring terminal 30, and the reinforcing resin portion 24 is formed to the outer region from the peripheral part of the connection portion 32. By doing like this, the reinforcing resin portion 24 is filled under the peripheral part of the connection portion 32 of the spring terminal 30, therefore the mechanical connection strength of the spring terminal 30 can be enhanced further more.

In addition, the connection portion 32 of the spring terminal 30 is connected to the wiring substrate 10 via the solder layer 22 which has an enough joining area. Therefore, reliability of the electrical connection can be ensured.

As another mode, the solder layer 22 may be arranged on the whole lower surface of the connection portion 32 of the spring terminal 30. In this case, the reinforcing resin portion 24 is formed to the outer region from the outer peripheral end of the connection portion 32 of the spring terminal 30.

The inventor of this application actually made the substrate (test sample) to which the spring terminals are connected by the same resin contained solder paste as that in FIG. 6, and the substrate (comparative sample) to which the spring terminals are connected by the normal solder paste.

Then, shear strength of the spring terminal was actually measured in the test sample and the comparative sample, and both samples were compared with each other. The measurement of the shear strength was done at an initial time at which no stress is applied, after the sample is processed for 500 hours in an atmosphere of 150° C., and after the sample was processed for 1000 hours in an atmosphere of 150° C., respectively.

According to the results, in the comparative sample in which the normal solder paste was used, average strength at an initial time was 549 gf, average strength after the process was applied for 500 hour was 443 gf, and average strength after the process was applied for 1000 hour was decreased to 271 gf.

In contrast, in the test sample of the present embodiment in which the resin contained solder paste was used, average strength at an initial time was 1126 gf, average strength after the process was applied for 500 hours was 1047 gf, and average strength after the process was applied for 1000 hour was 1051 gf.

In this manner, in the spring terminals which were reinforced with the resin reinforcing portion in the present embodiment, it was checked that about two times shear strength of the comparative sample was obtained, a large decrease of shear strength did not appear even when the stress was applied in a heating atmosphere, and high reliability was obtained.

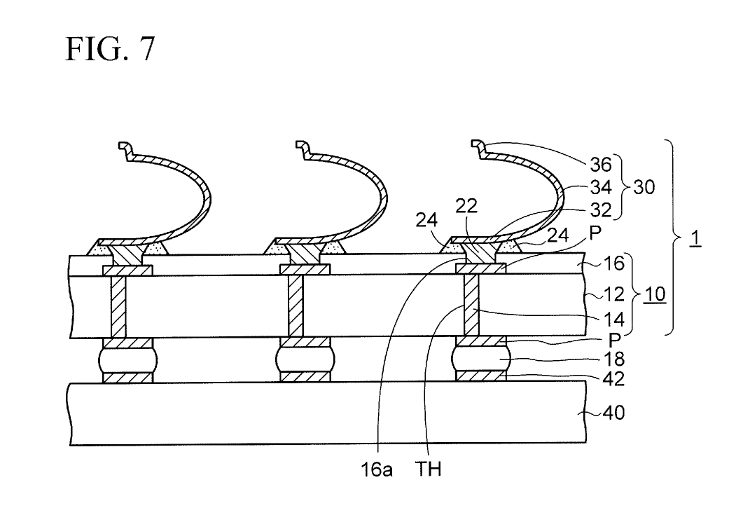

Next, an example in which the substrate with spring terminals 1 of the present embodiment is used as the mounting socket will be explained hereunder. As depicted in FIG. 7, the solder bumps 18 formed on the lower surface side of the substrate with spring terminals 1 in FIG. 6 are arranged on connection electrodes 42 of a mounting substrate 40 (mother board), and then the reflow heating is performed. By this matter, the solder bumps 18 of the substrate with spring terminals 1 are joined to the connection electrodes 42 of the mounting substrate 40.

At this time, when the reflow heating is performed, the solder layer 22 fixing the spring terminal 30 melts again. However, the spring terminal 30 is reinforced with the reinforcing resin portion 24 which is formed around the solder layer 22. Therefore, there is no fear that the spring terminal 30 moves and is displaced, or falls down.

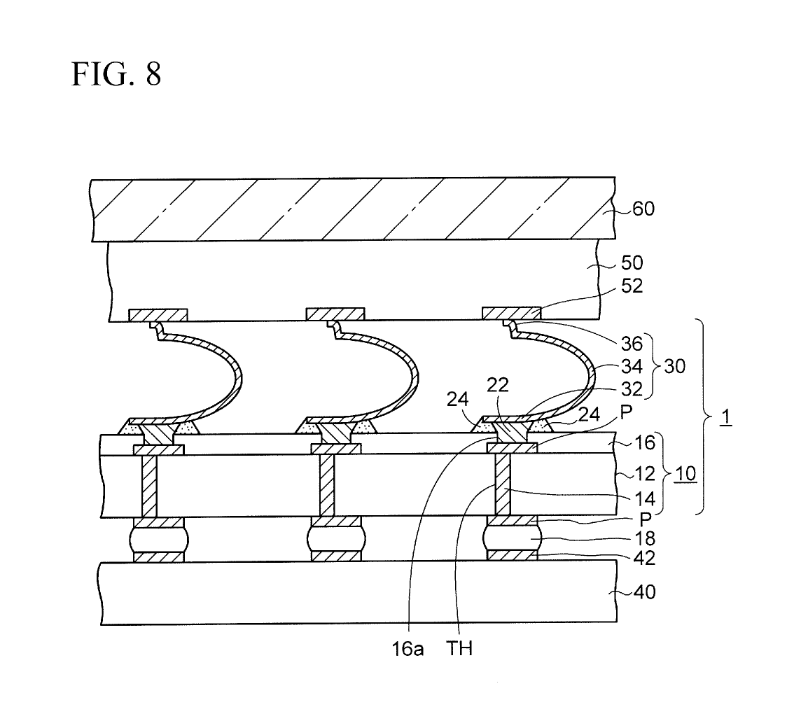

Then, as depicted in FIG. 8, a semiconductor package 50 is prepared. The external connection system of the semiconductor package 50 is of LGA (Land Grid Array) type, and includes the external connection electrodes 52 (lands) of the bumpless type.

The external connection electrodes 52 (lands) of the semiconductor package 50 are arranged on the contact portions 36 of the spring terminals of the substrate with spring terminals 1. The spring terminals 30 of the substrate with spring terminals 1 are provided to correspond to the external connection electrodes 52 of the semiconductor package 50.

Then, the semiconductor package 50 is pushed to the direction of the substrate with spring terminals 1 by a pressure cap 60 which is coupled to the substrate with spring terminals 1.

By this matter, the spring terminals 30 are pushed to the lower side, and then the external connection electrodes 52 of the semiconductor package 50 surely contact the contact portions 36 of the spring terminals 30 by an elastic force of the spring terminals 30, that tries to return toward the upper side. Therefore, the conduction between the semiconductor package 50 and the spring terminals 30 can be obtained.

In this manner, the semiconductor package 50 is electrically connected to the mounting substrate 40 via the substrate with spring terminals 1 which has a pitch conversion function. In the substrate with spring terminals 1 of the present embodiment, when the semiconductor package 50 is connected to the mounting substrate 40, there is no risk that the spring terminal 30 moves and is displaced, or falls down. Therefore, the semiconductor package 50 can be electrically connected to the mounting substrate 40 with good reliability.

The substrate with spring terminals 1 functions as the socket, and when the removal of the semiconductor package 50 is needed due to the fault, or the like, the pressure cap 60 can be removed. As a result, the spring terminals 30 of the substrate with spring terminals 1 return to their original positions by the elastic force, and thus the semiconductor package 50 can be removed easily from the substrate with spring terminals 1.

Here, similarly the spring terminals 30 may be provided to the connection pads P on both sides of the wiring substrate 10. In the case that the substrate with spring terminals including the spring terminals 30 on both surface sides, is applied to the mounting structure in FIG. 8, the substrate with spring terminals can be removed from the mounting substrate 40.

### Second Embodiment

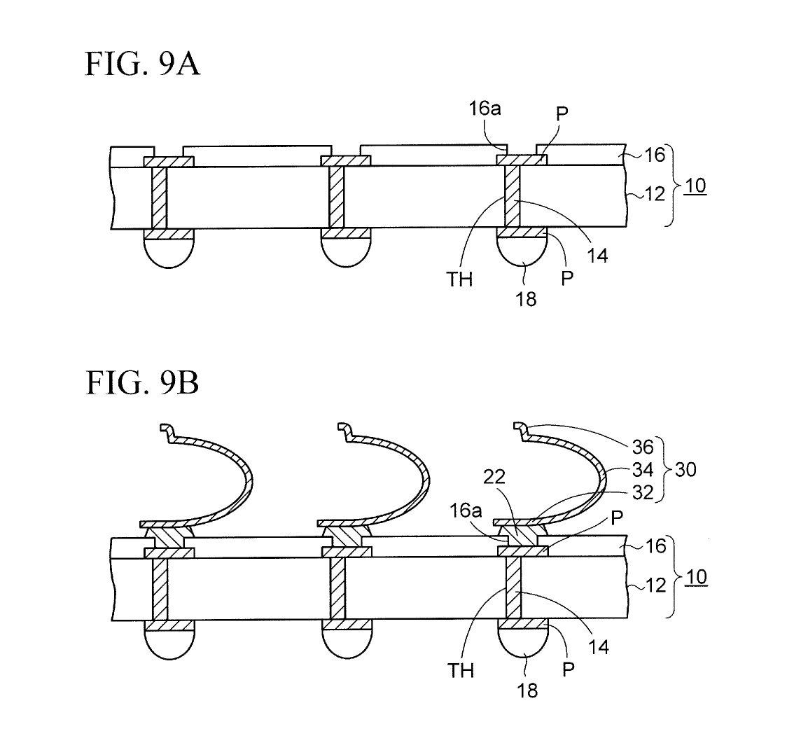

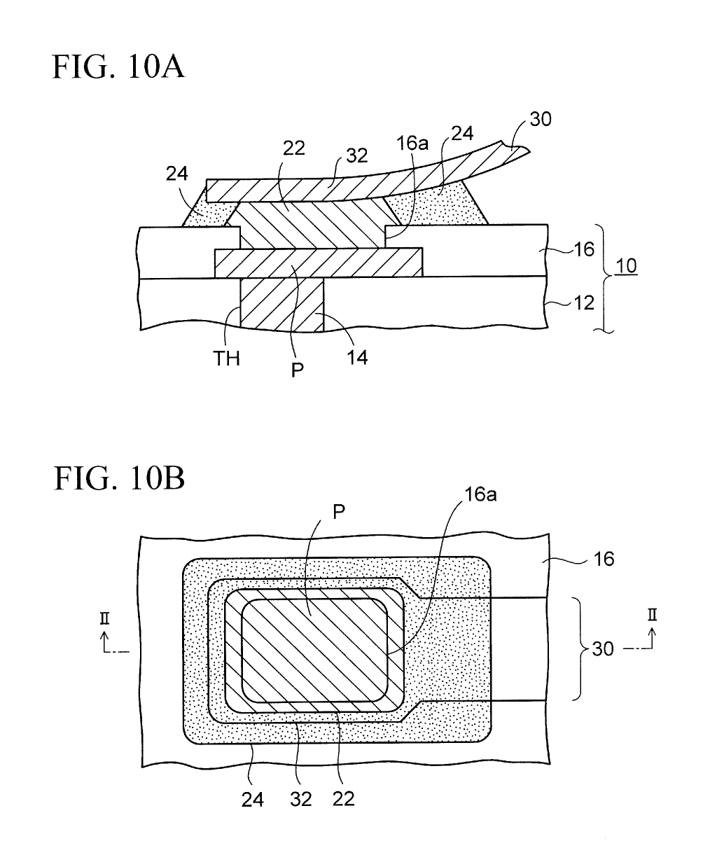

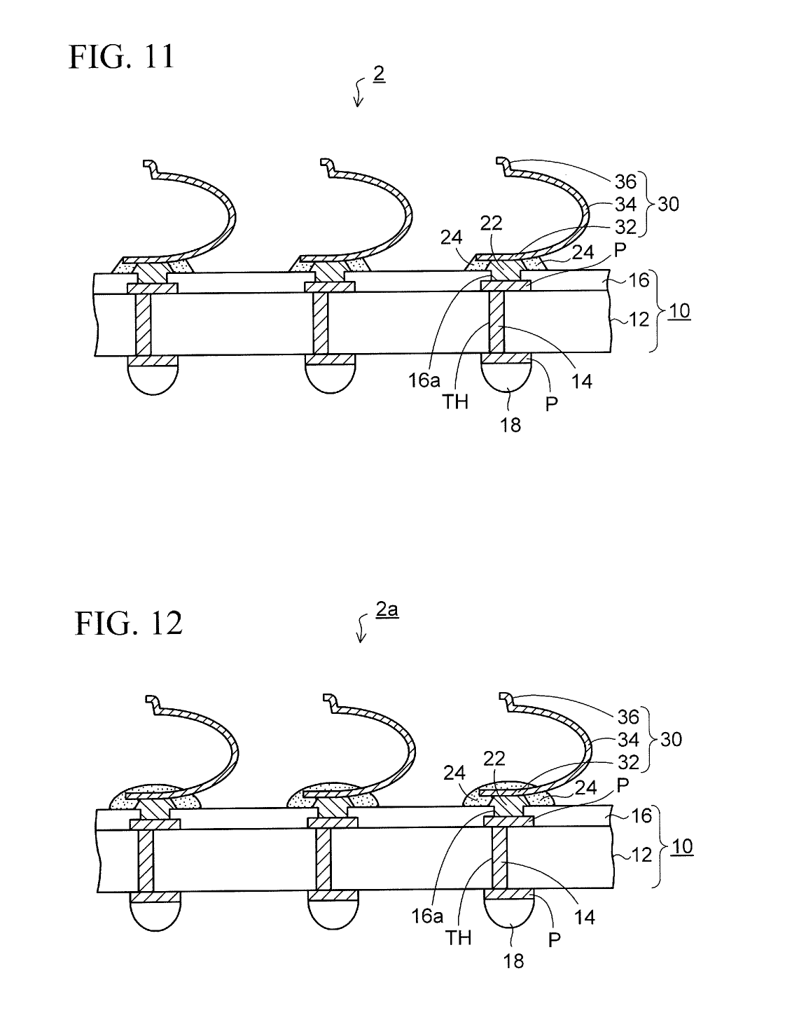

FIGS. 9A and 9B and FIGS. 10A and 10B are sectional views depicting a method of manufacturing a substrate with spring terminals according to a second embodiment, and FIG. 11 is a sectional view depicting a substrate with spring terminals according to the second embodiment. In the second embodiment, the resin contained solder paste is not used, but after the spring terminals are connected to the wiring substrate by the solder paste, the reinforcing resin portions are formed separately.

In the second embodiment, the same reference symbols are affixed to the same elements as those in the first embodiment, and their detailed explanation will be omitted herein.

In the method of manufacturing the substrate with spring terminals according to the second embodiment, as depicted in FIG. 9A, first, the same wiring substrate 10 as that of the first embodiment in FIG. 3A is prepared. Then, a solder paste (not shown) as the solder material is coated onto the connection pads P on the upper surface side of the wiring substrate 10 by the screen printing, the dispenser method, or the like.

Then, as depicted in FIG. 9B, according to the similar method to the first embodiment, the connection portions 32 of the spring terminals 30 are arranged on the solder paste (not shown) on the wiring substrate 10, and the reflow heating is performed. By this matter, the center main part of the connection portion 32 of the spring terminal 30 is connected to the connection pads P of the wiring substrate 10 by the solder layer 22.

Here, in place of the solder paste, the solder ball may be arranged on the connection pads P of the wiring substrate 10, and the reflow heating may be performed to connect each other in a state that the connection portions 32 of the spring terminals 30 are brought into contact with the solder balls.

Then, as depicted in FIGS. 10A and 10B, a resin is coated on the vicinity regions of the respective spring terminals 30 on the wiring substrate 10 by the dispenser, or the like, and also the resin is poured into the periphery parts of the connection portions 32 of the respective spring terminals 30.

As the resin, an ultraviolet (UV) curable or thermosetting epoxy resin, an ultraviolet (UV) curable ester resin or acrylic resin, or the like may be used. Then, such resin is cured by the heating process or the ultraviolet (UV) irradiation.

By this matter, like FIGS. 5A and 5B of the first embodiment, the reinforcing resin portion 24 covering the side surface of the solder layer 22 is formed to the outer region from the space between the peripheral part of the connection portion 32 of the spring terminal 30 and the wiring substrate 10 (the solder resist 16). FIG. 10A corresponds to a section taken along II-II of FIG. 10B.

With the above, as depicted in FIG. 11, a substrate with spring terminals 2 according to the second embodiment is obtained. In the substrate with spring terminals 2 of the second embodiment, like the first embodiment, the reinforcing resin portion 24 is formed to cover the side surface of the solder layer 22 connecting the spring terminal 30, and the mechanical connection strength of the spring terminal 30 is reinforced with the reinforcing resin portion 24.

Like a substrate with spring terminals 2a according to a first variation depicted in FIG. 12, in the substrate with spring terminals 2 in FIG. 11, the reinforcing resin portion 24 may be formed up to the upper surface of the spring terminal 30.

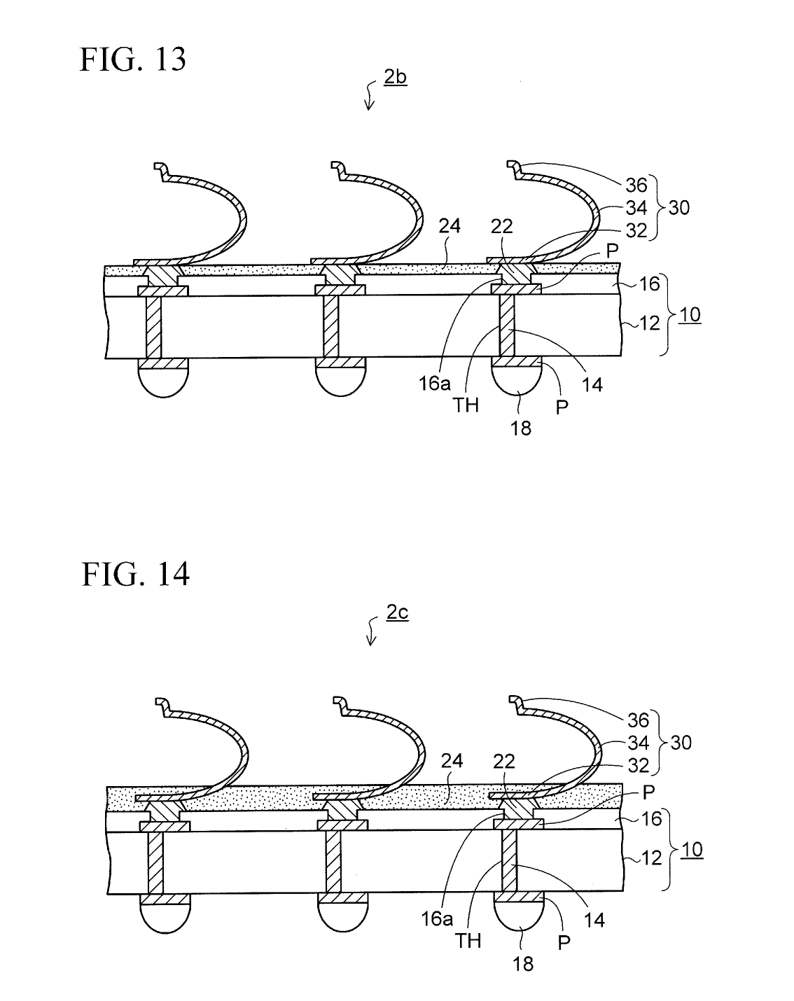

Also, like a substrate with spring terminals 2b according to a second variation depicted in FIG. 13, a resin may be formed integrally to the whole upper surface of the wiring substrate 10 from the space between the peripheral part of the connection portion 32 of the spring terminal 30 and the wiring substrate 10.

Alternatively, like a substrate with spring terminals 2c according to a third variation depicted in FIG. 14, a resin may be formed integrally on the whole upper surface of the wiring substrate 10 such that the space between the peripheral part of the connection portion 32 of the spring terminal 30 and the wiring substrate 10 is filled with the resin and also the upper surface of the connection portion 32 is covered with the resin.

Similarly to FIG. 8 in the first embodiment, in the substrate with spring terminal 2, 2a, 2b, or 2c of the second embodiment, the wiring substrate 10 is connected to the mounting substrate 40, then the semiconductor package 50 is connected to the spring terminals 30, and then the pressure cap 60 is provided.

Also in the substrate with spring terminal 2, 2a, 2b, or 2c of the second embodiment, when such substrate is connected to the mounting substrate 40, even though the solder layer 22 fixing the spring terminal 30 melts again, there is no risk that the spring terminal 30 moves and is displaced, or falls down. As a result, the semiconductor package 50 can be connected to the substrate with spring terminal 2, 2a, 2b, or 2c with good reliability.

All examples and conditional language recited herein are intended for pedagogical purpose to aid the reader in understanding the invention and the concepts contributed by the inventor to furthering the art, and are to be construed as being without limitation to such specifically recited examples and conditions, nor does the organization of such examples in the specification relates to a showing of the superiority and interiority of the invention. Although the embodiments of the present invention have been described in detail, it should be understood that the various changes, substitutions, and alterations could be made hereto without departing from the spirit and scope of the invention.

What is claimed is:

1. A substrate with spring terminals, comprising:
a substrate including a connection pad;
a spring terminal whose connection portion is connected to the connection pad by a solder layer; and
a resin portion formed to cover a side surface of the solder layer.

2. A substrate with spring terminals according to claim 1, wherein the solder layer is arranged in a center part of the connection portion, and
the resin portion is formed between a peripheral part of the connection portion and the substrate.

3. A substrate with spring terminals according to claim 1, wherein the resin portion is formed to cover an upper surface of the connection portion.

4. A method of manufacturing a substrate with spring terminals, comprising:
providing a resin contained solder material on a connection pad of a substrate; and
arranging a connection portion of a spring terminal on the resin contained solder material, and then connecting the connection portion to the connection pad by a solder layer and forming a resin portion covering a side surface of the solder layer, by performing a reflow heating.

5. A method of manufacturing a substrate with spring terminals, comprising:
providing a solder material on a connection pad of a substrate;
arranging a connection portion of a spring terminal on the solder material, and then connecting the connection portion to the connection pad by a solder layer, by performing a reflow heating; and
forming a resin portion covering a side surface of the solder layer.

6. A method of manufacturing a substrate with spring terminals, according to claim 4, wherein the solder layer is arranged in a center part of the connection portion, and
the resin portion is formed between a peripheral part of the connection portion and the substrate.

7. A method of manufacturing a substrate with spring terminals, according to claim 4, wherein the resin portion is formed to cover an upper surface of the connection portion.

8. A method of manufacturing a substrate with spring terminals, according to claim 4, wherein the resin contained solder material is a resin contained solder paste including a flux which has reactivity to a resin,
when the reflow heating is performed to the resin contained solder paste, the flux does not remain, and a step of cleaning the flux is omitted.

9. A method of manufacturing a substrate with spring terminals, according to claim 4, wherein a resin included in the resin contained solder material is a thermosetting resin.

10. A method of manufacturing a substrate with spring terminals, according to claim 5, wherein a resin of the resin portion is made of an ultraviolet curable resin or thermosetting resin.

11. A method of manufacturing a substrate with spring terminals, according to claim 5, wherein the solder layer is arranged in a center part of the connection portion, and
the resin portion is formed between a peripheral part of the connection portion and the substrate.

12. A method of manufacturing a substrate with spring terminals, according to claim 5, wherein the resin portion is formed to cover an upper surface of the connection portion.
